(19) United States
(12) Patent Application Publication
(10) Pub. No.: US 2002/0086502 A1
(43) Pub. Date: Jul. 4, 2002

(54) Method of forming a doped region in a semiconductor material

(76) Inventors: Mark Y. Liu, Portland, OR (US); Mitchell C. Taylor, Lake Oswego, OR (US); Shaofeng Yu, Lake Oswego, OR (US)

Correspondence Address: Michael A. Bernadicou, BLAKELY, SOKOLOFF, TAYLOR & ZAFMAN LLP, Seventh Floor, 12400 Wilshire Boulevard, Los Angeles, CA, 90025-1026, US

(21) Appl. No.: 09/751,217

(22) Filed: Dec. 29, 2000

(51) Int. Cl. H01L 21/425

(52) U.S. Cl. 438/530

(57) ABSTRACT

A method of forming a doped region. According to the present invention ions are implanted into a semiconductor material. The ion implanted semiconductor material is then laser annealed to form a doped semiconductor region.

### BACKGROUND OF THE INVENTION

1. Field of the Invention

The present invention relates to the field of semiconductor processing and more specifically to a method for forming a doped region in a semiconductor substrate.

2. Discussion of Related Art

Ultra-shallow source/drain extensions are fundamental building blocks for CMOS transistors. Conventionally, the source/drain extensions are fabricated using low energy ion implantation followed by a rapid thermal annealing process. The limitation of fabricating ultra-shallow junction used to be the implanters which implanted the dopants too deep into the substrate. With currently available electron-volt implanters which can place dopants very near the silicon surface, the limitations of this approach have become that the rapid thermal process causes to much undesired diffusion of dopants into the substrate and that the rapid thermal process has a low electric activation.

A newer approach of forming shallow source drain extensions is called projection gas immersion laser doping (P-GILD). In this technology, the silicon substrate is immersed in a dopant gas ambient and a pulsed ultra-violet laser beam is directly illuminated on the silicon. The laser energy is absorbed by the silicon causes a very thin layer of silicon to melt. The dopants in the ambient gas then diffuse into the moltant silicon and the diffusion stops at the liquid/solid interface since the diffusion coefficient is much smaller in solid silicon than in liquid silicon. By melting a very shallow layer of silicon, the doping junction depth can be very shallow. Unfortunately, this technique requires that the dopants diffuse over the gas/liquid interface and thus surface preparation is critical.

### BRIEF DESCRIPTION OF THE DRAWINGS

FIG. 1 is an illustration of a cross-sectional view of a silicon substrate having a gate dielectric and gate electrode formed thereon.

FIG. 2 is an illustration of a cross-sectional view showing the structure of FIG. 1 after a pre-amorphization ion implantation.

FIG. 3 is an illustration of a cross-sectional view of the substrate of FIG. 2 after a low energy ion implantation for a pair of tip regions.

FIG. 4 is an illustration of a cross-sectional view of the substrate of FIG. 3 after a laser anneal.

FIG. 5 is an illustration of a cross-sectional view of the substrate of FIG. 4 after an ion implantation step for a pair of deep source/drain regions.

FIG. 6 is an illustration of a cross-sectional view of the substrate of FIG. 5 after a laser anneal.

### DETAILED DESCRIPTION OF THE PRESENT INVENTION

The present invention is a method of forming a doped region in a semiconductor substrate on material. In the following description numerous specific details, such as specific materials, dimensions and processes are set forth in order to provide a thorough understanding of the present invention. However, one of ordinary skill in the art, will realize that the invention maybe practiced without these particular details. In other instances, well-known semiconductor equipment and processes have not been described in particular detail so as to void unnecessarily obscuring the present invention.

The present invention is a method of forming a doped region in a semiconductor substrate. According to the present invention, ions are implanted into a crystalline semiconductor substrate and then are laser annealed to form a doped region. The dopants are ion implanted at a low energy, preferably less than 1 KeV, so that they are placed at a depth shallower than the melting depth of silicon when exposed to a laser beam during a laser annealing process. By placing dopants shallower than the melting depth of silicon, the annealing of the implant damage and activation of the implanted dopants takes place in the liquid phase and stops at the liquid-solid interface, thereby, enabling a junction to be formed which is very shallow and abrupt. Additionally, because the laser anneal melts a thin layer of silicon and because dopant solubility in a liquid is greater than in a solid, a flat dopant concentration profile and high electric activation can be achieved. Still further, because dopants are implanted into the silicon substrate prior to the laser annealing, the dopants do not need to go through a gas/liquid interface thereby enabling uniform junctions to be formed across a wafer and from wafer to wafer. The combination of a low energy ion implantation and a laser anneal in accordance with the present invention is ideal for use in the manufacture of source/drain extensions for metal oxide semiconductor (MOS) transistors.

The present invention will now be described with respect to the formation of an MOS transistor. It is to be appreciated that the present invention is not to be limited to this specific example and is equally useful in the manufacture of other types of semiconductor devices, such as bipolar transistors or memory devices where doped regions are used.

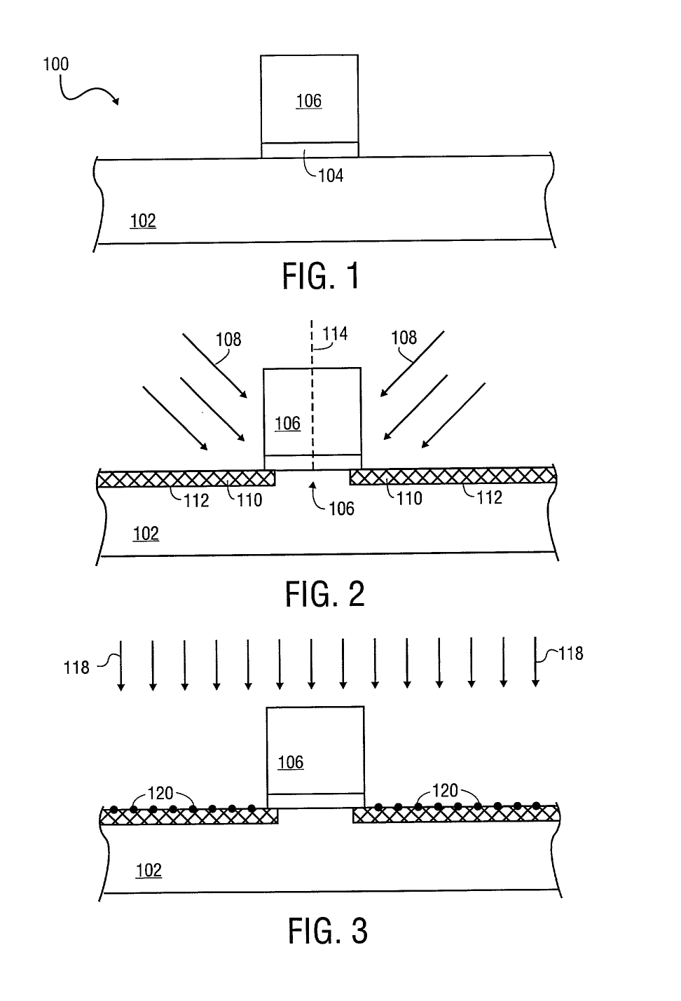

The fabrication of an MOS transistor begins by providing a substrate 100 on which the device is to be fabricated. Substrate 100 will typically include a monocrystalline silicon substrate 102 having a doping density of about 1×10¹⁸/cm³ of a first conductivity type dopant (i.e., p type dopants, such as boron or n type dopants, such as arsenic or phosphorous) as shown in FIG. 1. A gate dielectric 104, such as silicon dioxide or silicon oxy-nitride is formed on the monocrystalline silicon substrate 102. A gate electrode 106 comprising, for example, doped polycrystalline silicon is formed on the gate dielectric 104. It is to be appreciated that silicon substrate 102 need not necessarily be a silicon monocrystalline silicon substrate and can be or include, for example, deposited epitaxial silicon layers (e.g., epi layers) or other crystalline semiconductor substrates or materials as is well-known in the art.

The first step, in an embodiment of the present invention, is to conduct a pre-amorphization implant 108 to amorphorize a thin layer of silicon 110 as shown in FIG. 2. Silicon or germanium atoms can be implanted into the silicon substrate 102 to cause the monocrystalline silicon to convert to amorphous silicon. (Silicon atoms can be implanted at a dose of between 5×10¹⁴-2×10¹⁵/cm² while germanium atoms can be implanted at a dose of between 2×10¹⁴-1×10¹⁵/cm².) Because amorphous silicon has a lower melting temperature than crystalline silicon, the amorphous silicon regions 110 will melt at a lower laser power than the crystalline silicon 102 enabling one to control the melting depth of a subsequent laser annealing step to stop at the amorphous silicon/crystalline silicon interface 112. Utilizing a high angle implant (e.g., an angle of between 10-45° from an axis 114 perpendicular to the substrate surface) enables silicon or germanium atoms to be positioned laterally beneath the sidewalls of the gate electrode, thereby, allowing the amorphous silicon 110 to be formed laterally beneath the sidewalls of the gate electrode 106. As will be seen, the amount of overlap by the gate electrode 106 over the amorphous silicon regions 110 will be able to be used to precisely control the amount of overlap of the tip or source/drain extension regions. The ability to control the amount of overlap of the tip regions is necessary to ensure proper operation of the MOS device. Generally, about 3-15 nanometers of overlap by each side of the gate electrode, is desired. The gate electrode 106 shields the channel region 116 from the pre-amorphization implant thereby leaving the channel region 116 as crystalline silicon. It is to be appreciated that a pre-amorphization implant is not required in order to practice the present invention. It is, however, desirable to use a pre-amorphaization implant whenever the exact depth of the junction of doped region is desired and/or when the doped region is to be formed beneath a structure, such as gate electrode 106.

Next, as shown in FIG. 3, a low energy ion implantation process 118 is used to place dopants 120 of a conductivity type opposite the conductivity type of the silicon substrate 102 (i.e., p type ions for n type silicon substrate 102 or n type ions for p type silicon substrate 102) into the surface of the silicon substrate 102 (or the amorphous silicon regions 110, if used). The dopants are implanted in alignment with the outside edges of the gate electrode 106 as shown in FIG. 3. The ions 120 are implanted to a depth which is shallower than the melting depth of the silicon during the subsequent anneal process. The dopants 120 are preferably implanted at an energy of less than 1 KeV in a direction perpendicular to the wafer surface and at a dose between 1×10¹⁵-1×10¹⁶/cm². If p type extensions are desired, then boron atoms can be implanted an energy of between 200 eV-10 KeV and if n type extensions are desired then arsenic or phosphorous atoms can be implanted at an energy of between 200 eV-5 KeV. Any well-known low energy ion implantation systems, such as Applied Materials XR-LEAP can be used.

Next, as shown in FIG. 4, substrate 100 is exposed to a laser beam 121 during a laser anneal process to form a pair tip or source/drain extensions 122 on laterally opposite sides of gate electrode 106. The laser beam 121 illuminates the silicon and causes the solid phase silicon substrate (and/or the amorphous silicon 110, if used) to melt into a liquid or molten phase of silicon. The pulse width (pulse time) and fluence (energy per area) of the laser process is used to control the melting depth of the silicon substrate 102, which also determines the depth of the silicon/source drain extensions. Generally, source/drain extension 122 having a depth of between 100-500 Å are desired, so the laser pulse and fluence are chosen to produce a melting depth of about 100-500 Å. A pulse width between 10-100 nanoseconds and a fluence of between 0.3-1.0 joule/cm² can be used.

The laser anneal process both activates the dopants and causes diffusion of the dopants throughout the liquid face silicon. The diffusion of dopants in liquid phase silicon is about eight orders of magnitude higher than the diffusion of dopants in solid phase silicon. Dopants will therefore diffuse uniformly throughout the liquid phase silicon and stop at the liquid-solid interface. Additionally, since dopant activation is dependent upon solubility, the activation is not limited to the higher solubility of the dopants in solid silicon but rather by the solubility of the dopants in liquid silicon. In this way, a pair of tip or source/drain extension 122 which have a flat doping concentration profile and high activation can be achieved. After the laser exposure the liquid phase silicon converts back to solid crystalline silicon and the dopants are incorporated into the lattice.

It is appreciated that the gate electrode 106 prevents the channel region 116 from being exposed by the laser 121 and from melting and enabling dopants to diffuse into the channel region. Additionally, if a pre-amorphous implant is used, and because the energy level required to melt amorphous silicon is less than crystalline silicon, the amorphous silicon 110 beneath the gate electrode is able to melt and thereby enable the implanted dopants to diffuse laterally beneath the sidewalls of the gate electrode 106 and thereby form overlap tip regions as required for reliable device performance.

A pulsed laser, such as an Exchimer laser having a wavelength of approximately 308 nanometers or a Yag laser having a wavelenght of approximately 532 nanometers can be used for the laser anneal process. Such pulsed lasers will typically expose a single di of wafer at a time.

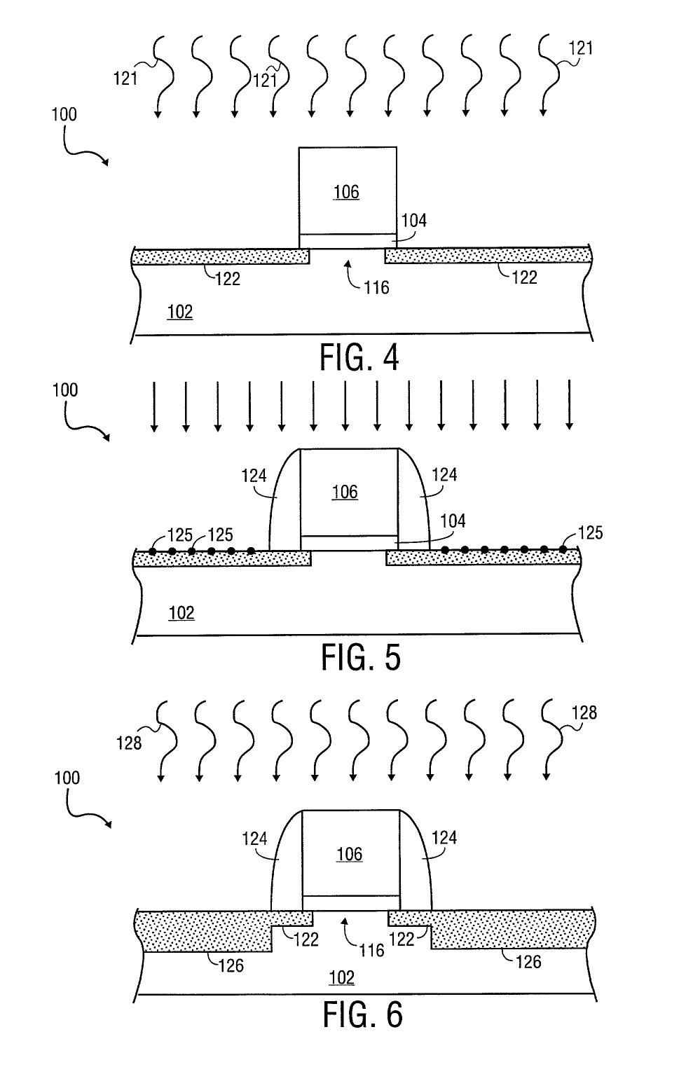

Next, the processing of substrate 100 can be continued to form deep source/drain junctions. According to an embodiment of the present invention, the low energy/laser anneal process of the present invention is used to form deep source/drain junctions. Accordingly, as shown in FIG. 5, a pair of sidewall spacers 124 are formed along laterally opposite sidewall of gate electrode 106 and over tip regions 122. Spacers 124 can be formed by any well-known technique such as by blanket depositing a spacer film over the substrate 100 and then anisotropically etching the spacer film to form spacers 124. Spacers 124 typically have a width of between 300-100 Å. Next, as also shown in FIG. 5, substrate 100 is ion implanted with ions of the same conductivity type as tip regions 122. The ions are implanted into the substrate 100 at an angle substantially perpendicular to the surface of the substrate and in alignment with the outside edges of spacers 124. Spacers 124 prevent the tip regions from being implanted during this step. Additionally, the gate electrode 106 prevents the channel region from being implanted. The dopants are implanted to a depth less than the depth desired for the deep source/drain regions. That is, the ions 125 are implanted to a depth less than the melting depth of the silicon substrate during the subsequent laser annealing process for the deep source/drain regions. If boron is implanted, it can be implanted at an energy of between 1 KeV-20 KeV and is arsenic is implanted it can be implanted at an energy of between 4 KeV-40 KeV. The same dosages as used for the tip regions 122 can be used.

Next, as shown in FIG. 6, substrate 100 is exposed to a laser beam 128 to form deep source/drain regions 126. Substrate 100 can be laser annealed as described above, but with a larger amount of energy (e.g., fluence of 0.6-1.5 joule/cm²) to cause the melting of the silicon substrate to a deeper depth desired for the deep source/drain regions. It is to be appreciated that the laser beam 128 does not melt the spacers because is not absorbed by nitride or oxide. Oxide or nitride scatters the laser beam and reduces its intensity when it reaches the silicon substrate 102. In this way, the silicon substrate underlying the spacers 124 does not melt and the abrupt junctions of the tip regions 122 beneath the spacers remain intact. As such, deep source/drain regions 126 are formed which are in direct horizontal alignment with the outside edges of spacers 124. As can be seen, the ion implantation/laser anneal doping technique of the present invention is truly localized, not only in the vertical dimension, but also in the lateral direction (e.g., only silicon under exposure of the laser is annealed). In this way, source/drain regions with abrupt junctions can be reliably and uniformly fabricated. The ion implantation/laser anneal doping process of the present invention enables the precise tailoring or engineering of the source/drain regions thereby improving the reliability and performance of the fabricated MOS transistors. At this time, standard MOS transistor fabrication techniques, such as formation of silicide regions on the deep source/drain regions 126 by a salicide process, can be used to complete fabrication of the device.

Although the present invention has been described with respect to the formation of source/drain regions of an MOS device, the present invention can be used to form any doped region. Additionally, although the present invention has been described with respect to the formation of source/drain regions of opposite conductivity type than the substrate in which they are formed, the present invention can be used to form doped regions in a silicon substrate of the same conductivity type as desired of the doped region. For example, the present invention can be used to form halo or punchthough stop regions in a silicon substrate prior to the formation of source/drain regions. Punchthrough stop regions have the same conductivity type, but a higher concentration than the silicon substrate in which they are formed. Thus, the present invention can be applied to the formation of any doped region in any type of semiconductor substrate or material.

Thus, a method of forming a doped region in a semiconductor material has been described.

We claim:

1. A method of forming a doped region comprising:
ion implanting dopants into a semiconductor material; and
laser annealing said ion implanted semiconductor material.

2. The method of claim 1 wherein said semiconductor material comprises silicon.

3. The method of claim 2 wherein said dopants are selected from the group consisting of boron, arsenic, and phosphorus.

4. The method of claim 1 wherein said ions are implanted at an energy of less than 1 KeV.

5. The method of claim 1 wherein said ions are implanted at a depth less than the melting depth of said semiconductor material when exposed to said laser annealing step.

6. The method of claim 1 wherein said ion implanted semiconductor material is laser annealed with a pulse laser having a wave length of approximately 308 nanometers.

7. The method of claim 1 wherein said ion implanted semiconductor material is laser annealed with a pulse laser having a wavelength of approximately 532 nanometers.

8. The method of claim 1 wherein ion implanted semiconductor material is laser annealed by a laser having a pulse width of between 10-100 nanoseconds.

9. A method of forming a transistor comprising:
forming a gate electrode on a gate dielectric on a silicon substrate having a first conductivity type;
ion implanting dopants of a second conductivity type into said silicon substrate on opposite sides of said gate electrode; and
laser annealing said substrate to activate said ion implanted dopants and to form source/drain regions on opposite sides of said gate electrode.

10. The method of claim 9 further comprising after said gate electrode and prior to ion implanting said dopants, ion implanting silicon or germanium ions beneath the edges of said gate electrode.

11. The method of claim 10 wherein said silicon or germanium ions are ion implanted utilizing a 10-45° from normal ion implantation angle.

12. The method of claim 10 wherein said silicon or germanium ions are ion implanted at a dose between 2×10¹⁴-2×10¹⁵ ions/cm².

13. The method of claim 9 wherein said ions are ion implanted at a depth less than the melting depth of said silicon substrate when exposed to said laser annealing step.

14. A method of forming a transistor comprising:
forming a gate electrode having laterally opposite sidewalls on a gate dielectric on a silicon substrate having a first conductivity type;
ion implanting silicon or germanium ions into said silicon substrate on laterally opposite sides of said gate electrode and beneath the sidewalls of said gate electrodes utilizing a large angle ion implantation;
ion implanting dopants of a second conductivity type into said semiconductor substrate on opposite sides of said gate electrodes;
laser annealing said ion implanted semiconductor substrate to activate said dopants to form a pair of source/drain tip regions on opposite sides of said gate electrode wherein said tip regions extend beneath the sidewalls of said gate electrode;
forming a pair of sidewall spacers on opposite sides of said gate electrode;
ion implanting dopants of a second conductivity type on opposite sides of said pair of sidewall spacers and into said semiconductor substrate; and
laser annealing said ion implanted dopants on laterally opposites sides of said sidewalls to form a pair of deep source/drain region on opposite sides of said sidewall spacers.

15. The method of claim 14 wherein said tip regions extend between 3-15 nanometers beneath said gate electrode.

16. The method of claim 14 wherein said first conductivity type is p type and said second conductivity type is n type.

17. The method of claim 14 wherein said first conductivity type is n type and said second conductivity type is p type.
